(19) United States
(12) Patent Application Publication
(10) Pub. No.: US 2016/0149061 A1
(43) Pub. Date: May 26, 2016

(54) METAL CHALCOGENIDE NANOPARTICLES FOR MANUFACTURING SOLAR CELL LIGHT ABSORPTION LAYERS AND METHOD OF MANUFACTURING THE SAME

(71) Applicant: LG CHEM, LTD., Seoul (KR)

(72) Inventors: Seokhee YOON, Daejeon (KR); Eun Ju PARK, Daejeon (KR); Hosub LEE, Daejeon (KR); Seokhyun YOON, Daejeon (KR)

(21) Appl. No.: 14/898,079

(22) PCT Filed: Aug. 1, 2014
(86) PCT No.: PCT/KR2014/007090

§ 371 Date: Dec. 11, 2015

(30) Foreign Application Priority Data
Aug. 1, 2013 (KR) 10-2013-0091778
Aug. 1, 2013 (KR) 10-2013-0091781

(51) Int. Cl. H01L 31/0384; C09D 11/52; C09D 5/32; H01L 31/032

(52) U.S. Cl. CPC H01L 31/0384; H01L 31/0326; C09D 11/52; C09D 5/32

(57) ABSTRACT

Disclosed are metal chalcogenide nanoparticles forming light absorption lavers of solar cells including two or more phases selected from a first phase including zinc (Zn)-containing chalcogenide, a second phase including tin (Sn)-containing chalcogenide and a third phase including copper (Cu)-containing chalcogenide, and a method of manufacturing the same.

### TECHNICAL FIELD

The present invention relates to metal chalcogenide nanoparticles for manufacturing solar cell light absorption layers and a method of manufacturing the same.

### BACKGROUND ART

Solar cells have been manufactured using a light absorption layer formed at high cost and silicon (Si) as a semiconductor material since an early stage of development. To more economically manufacture commercially viable solar cells, structures of thin film solar cells, using an inexpensive light absorbing material such as copper indium gallium sulfo (di) selenide (CIGS) or Cu(In, Ga)(S, Se)₂, have been developed. Such CIGS-based solar cells typically include a rear electrode layer, an n-type junction part, and a p-type light absorption layer. Solar cells including such CIGS layers have a power conversion efficiency of greater than 19%. However, in spite of potential for CIGS-based thin film solar cells, costs and insufficient supply of In are main obstacles to widespread commercial application of thin film solar cells using CIGS-based light absorption layers. Thus, there is an urgent need to develop solar cells using In-free or low-cost universal elements.

Accordingly, as an alternative to the CIGS-based light absorption layer, CZTS(Cu₂ZnSn(S,Se)₄)-based solar cells including copper (Cu), zinc (Zn), tin (Sn), sulfur (S), or selenium (Se), which are extremely cheap elements, have recently received attention. CZTS has a direct band gap of about 1.0 eV to about 1.5 eV and an absorption coefficient of 10⁴ cm⁻¹ or more, reserves thereof are relatively high, and CZTS uses Sn and Zn, which are inexpensive.

In 1996, CZTS hetero junction PV batteries were reported for the first time, but CZTS-based solar cells have been less advanced than CIGS-based solar cells and photoelectric efficiency of CZTS-based solar cells is 10% or less, much lower than that of CIGS-based solar cells. Thin films of CZTS are manufactured by sputtering, hybrid sputtering, pulsed laser deposition, spray pyrolysis, electro-deposition/thermal sulfurization, e-beam processing, Cu/Zn/Sn/thermal sulfurization, and a sol-gel method.

Meanwhile, PCT/US/2010-035792 discloses formation of a thin film through heat treatment of ink including CZTS/Se nanoparticles on a base. Generally, when a CZTS thin film is formed with CZTS/Se nanoparticles, it is difficult to enlarge crystal size at a forming process of a thin film due to previously formed small crystals. In addition, when each grain is small, interfaces are extended and thereby electron loss occurs at interfaces, and, accordingly, efficiency is deteriorated. Furthermore, to enlarge grain size using CZTS/Se nanoparticles, extremely long heat treatment period is required and thereby it is extremely inefficient in terms of cost and time.

Thus, it is preferable to use nanoparticles, which are used in thin films, including Cu, Zn and Sn, and precursor type particles, which may be changed to CZTS/Se during a thin film process, instead of CZTS/Se crystals for grain growth and shortening of process time. As the precursor, metal nanoparticles or binary compound particles consisting of a metal element and Group VI element may be used. However, when a mixture of metal nanoparticles are used or the binary compound is used, the particles or element is not mixed homogenously and sufficiently in an ink composition and thereby the metal nanoparticles may be easily oxidized, and, accordingly, it is difficult to obtain a CZTS/Se thin film of superior quality.

Therefore, there is a high need to develop a technology for manufacture of thin film solar cells, which are stable against oxidation and drawbacks of which are minimized due to a homogenous composition, including highly efficient light absorption layers.

### DISCLOSURE

### Technical Problem

Therefore, the present invention has been made to solve the above problems and other technical problems that have yet to be resolved.

As a result of a variety of intensive studies and various experiments, the inventors of the present invention developed metal chalcogenide nanoparticles including two or more phases selected from a first phase including zinc (Zn)-containing chalcogenide, a second phase including tin (Sn)-containing chalcogenide, and a third phase including copper (Cu)-containing chalcogenide and confirmed that, when a thin film was manufactured using the metal chalcogenide nanoparticles, the thin film has an entirely uniform composition and are stable against oxidation by adding S or Se to the nanoparticles. In addition, the inventors confirmed that, when a thin film was manufactured further including metal nanoparticles, particle volumes were extended, due to a Group VI element, at a selenization process and thereby light absorption layers having high density grew, and, accordingly, the amount of a Group VI element in a final thin film was increased, resulting in a superior quality thin film and thus completing the present invention.

### Technical Solution

In accordance with one aspect of the present invention, provided are metal chalcogenide nanoparticles forming light absorption layers of solar cells including two or more phases selected from a first phase including zinc (Zn)-containing chalcogenide, a second phase including tin (Sn)-containing chalcogenide, and a third phase including copper (Cu)-containing chalcogenide.

The term “chalcogenide” of the present invention means a material including a Group VI element, for example, sulfur (S) and/or selenium (Se). As one embodiment, the copper (Cu)-containing chalcogenide may be CuₓS (0.5≦x≦2.0) and/or Cu_{y}Se (0.5≦y≦2.0), the zinc (Zn)-containing chalcogenide may be ZnS and/or ZnSe, and the tin (Sn)-containing chalcogenide may be Sn_{z}S (0.5≦z≦2.0) and/or Sn_{w}Se (0.5≦w≦2.0) and may be at least one selected from the group consisting of, for example, SnS, SnS₂, SnSe and SnSe₂.

The metal chalcogenide nanoparticles may include two phases or three phases. These phases may exist independently in one metal chalcogenide nano particle or may be distributed having a uniform composition in one metal chalcogenide nano particle.

When the metal chalcogenide nanoparticles include two phases, the two phases may be all combinations which may be made from the first phase, the second phase and the third phase, and may be the first phase and the second phase, the second phase and the third phase, or the first phase and the third phase. When the metal chalcogenide nanoparticles include three phases, The metal chalcogenide nanoparticles may include the first phase, the second phase and the third phase.

Here, the metal chalcogenide nanoparticles according to the present invention are manufactured by a substitution reaction using reduction potential differences of zinc (Zn), tin (Sn) and copper (Cu) and, as such, metal ingredients to substitute and metal ingredients to be substituted may be uniformly present in the metal chalcogenide nanoparticles.

Meanwhile, when the metal chalcogenide nanoparticles include the first phase and third phase, a content ratio of copper and zinc may be freely controlled in a range of 0<Cu/Zn by controlling the equivalence ratio of a copper (Cu) salt based on zinc-containing chalcogenide and reaction conditions during a substitution reaction. In addition, in the metal chalcogenide nanoparticles including the second phase and third phase, a content ratio of copper and tin may be freely controlled in a range of 0<Cu/Sn by controlling the equivalence ratio of a copper (Cu) salt based on the molar ratio of tin-containing chalcogenide and reaction conditions during substitution reaction. A content ration of tin and zinc in nanoparticles including the first phase and the second phase also may be freely controlled in a range of 0<Sn/Zn.

Similarly, when the metal chalcogenide nanoparticles include the first phase, the second phase and the third phase, a composition ratio of zinc, tin, and copper also may be freely controlled by controlling the equivalence ratios of a tin (Sn) salt and copper (Cu) salt based on the initial molar ratio of the zinc-containing chalcogenide. However, when considering formation of a CZTS/Se thin film, a composition ratio of zinc, tin, and copper is preferably in a range of 0.5≦Cu/(Zn+Sn)≦1.5 and 0.5≦Zn/Sn≦2, more preferably in a range of 0.7≦Cu/(Zn+Sn)≦1.2 and 0.8≦Zn/Sn≦1.4.

Meanwhile, the morphology of the nanoparticles is not particularly limited and may be varied. As one embodiment, one phase forms a core and another phase forms a shell of two phases, one phase forms a core and the other two phases form a shell in a complex form of three phases, or two phases form a core in a complex form and the other phase forms a shell of three phases.

Alternative, as shown in FIGS. 1 and 2, the nanoparticles may have two phases uniformly distributed in entire particles or three phases uniformly distributed in entire particles.

The metal chalcogenide nanoparticles manufactured as described above may include a 0.5 to 3 mol of a Group VI element based on a 1 mol of the metal element.

Outside the above range, when too much of the metal element is included, sufficient supply of a Group VI element is impossible and thereby stable phases such as the above metal chalcogenide are not formed and, accordingly, in subsequent processes, phases may be changed or separated metals may be oxidized. On the contrary, when too much of the chalcogenide element is included, a Group VI source is evaporated during a heat treatment process for manufacture of a thin film and thereby a final thin film may have too many pores.

As one embodiment, the metal chalcogenide nanoparticles may be manufactured as follows.

First, a first precursor including zinc (Zn) or tin (Sn), and sulfur (S) or selenium (Se) is manufactured.

Some zinc (Zn) of the first precursor may be substituted with tin (Sn) and/or copper (Cu) using a reduction potential difference of metals, or some tin (Sn) of the first precursor may be substituted with copper (Cu) using a reduction potential difference of metals.

A manufacturing process of the first precursor, for example, includes:

(i) preparing a first solution including at least one a Group VI source selected from the group consisting of compounds including sulfur (S), or selenium (Se), or sulfur (S) and selenium (Se);

(ii) preparing a second solution including a zinc (Zn) salt or tin (Sn) salt; and

(iii) mixing and reacting the first solution and second solution.

Therefore, the first precursor may be zinc (Zn)-containing chalcogenide or tin (Sn)-containing chalcogenide. Subsequent processes differ depending on the first precursor types.

As one embodiment, when the first precursor is zinc (Zn)-containing chalcogenide, as described above, some zinc (Zn) may be substituted with tin (Sn) and/or copper (Cu) using a reduction potential difference of metals.

Here, zinc (Zn) may be substituted with tin (Sn) and/or copper (Cu) by mixing and reacting a product including zinc (Zn)-containing chalcogenide with a third solution including a tin (Sn) salt or copper (Cu) salt. Here, the inc (Zn)-containing chalcogenide may be reacted, at the same time, with a tin (Sn) salt and copper (Cu) salt by using a third solution including a tin (Sn) salt and copper (Cu) salt, or may be reacted sequentially with a third solution including a tin (Sn) salt and a fourth solution including a copper (Cu) salt in order of tin and copper. Meanwhile, when the first precursor is tin (Sn)-containing chalcogenide, due to the reduction potential difference of metals, some tin (Sn) may not be substituted with zinc (Zn) and may be substituted with copper (Cu).

Here, tin (Sn) may be substituted with copper (Cu) by mixing and reacting the third solution including a copper (Cu) salt with a product including tin (Sn)-containing chalcogenide.

The above reaction is carried out due to reduction potential differences of zinc, tin, and copper. Concretely, reduction potential order is zinc>tin>copper. The reduction potential may be measurement of electron loss levels. Thus, in solution state, ionization tendency of zinc is greater than that of tin and copper. In addition, ionization tendency of tin is greater than that of copper. Therefore, in zinc (Zn)-containing chalcogenide, zinc may be substituted with tin and copper. In addition, in tin (Sn)-containing chalcogenide, tin may be substituted with copper. However, it is not easy that copper is substitute with tin or zinc, or tin is substituted with zinc.

Meanwhile, in one embodiment, when the first solution and second solution are mixed, the Group VI source may be included in a range of 1 to 10 mol based on 1 mol of the zinc (Zn) salt or tin (Sn) salt.

Outside the range, when the Group VI source is included in a concentration of less than 1 mol, sufficient supply of the Group VI element is impossible and thereby a stable phase such as metal chalcogenide is not obtained in a large yield rate, and, accordingly, the phase may be changed or separated metals may be oxidized in a subsequent process. On the contrary, when the Group VI source is included in a concentration exceeding 10 mol, the Group VI source excessively remains as an impurity after reaction and thereby unevenness of particles may occur. Thus, when a thin film is manufactured with such uneven particles, the Group VI source is evaporated during a heat treatment process of the thin film, and, as such, pores may be excessively formed in a final thin film.

Here, if the second solution mixed with the first solution is reacted at a suitable temperature, zinc (Zn)-containing chalcogenide or tin (Sn)-containing chalcogenide nanoparticles having uniform composition and particle size may be obtained.

In a specific embodiment, solvents for the first solution to fourth solution may be at least one selected from the group consisting of water, alcohols, diethylene glycol (DEG), oleylamine, ethylene glycol, triethylene glycol, dimethyl sulfoxide, dimethyl formamide, and N-methyl-2-pyrrolidone (NMP). In particular, the alcohol solvents may be methanol, ethanol, propanol, butanol, pentanol, hexanol, heptanol and octanol having 1 to 8 carbons.

In a specific embodiment, the salt may be at least one salt selected from the group consisting of a chloride, a bromide, an iodide, a nitrate, a nitrite, a sulfate, an acetate, a sulfite, an acetylacetonate and a hydroxide. As the tin (Sn) salt, a divalent or tetravalent salt may be used, but embodiments of the present invention are not limited thereto.

In a specific embodiment, the Group VI source may be at least one salt selected from the group consisting of Se, Na₂Se, K₂Se, CaSe, (CH₃)₂Se, SeO₂, SeCl₄, H₂SeO₃, H₂SeO₄, Na₂S, K₂S, CaS, (CH₃)₂S, H₂SO₄, Na₂S₂O₃ and NH₂SO₃H, and hydrates thereof, thiourea, thioacetamide, and selenourea.

Meanwhile, the first solution to fourth solution may further comprise a capping agent.

The capping agent is included during a solution process and, as such, sizes and particle phases of synthesized metal chalcogenide nanoparticles may be controlled.

In addition, since the capping agent prevents condensation of synthesized metal chalcogenide nanoparticles, the third solution or fourth solution may be mixed when synthesized particles are in a uniformly distributed state, and, as such, metals may be uniformly substituted in total particles.

The capping agent is not particularly limited and may, for example, be at least one selected from the group consisting of polyvinylpyrrolidone, sodium L-tartrate dibasic dehydrate, potassium sodium tartrate, sodium acrylate, poly(acrylic acid sodium salt), poly(vinyl pyrrolidone), sodium citrate, trisodium citrate, disodium citrate, sodium gluconate, sodium ascorbate, sorbitol, triethyl phosphate, ethylene diamine, propylene diamine, 1,2-ethanedithiol, and ethanethiol.

The present invention also provides an ink composition for manufacturing light absorption layers including at least one of the metal chalcogenide nanoparticles.

In particular, the ink composition may be an ink composition including metal chalcogenide nanoparticles including all of the first phase, second phase, and third phase, an ink composition including metal chalcogenide nanoparticles including the first phase and third phase, an ink composition including metal chalcogenide nanoparticles including the first phase and second phase and metal chalcogenide nanoparticles including the second phase and third phase, or an ink composition including metal chalcogenide nanoparticles including the first phase and second phase and metal chalcogenide nanoparticles including the first phase and third phase.

In addition, the ink composition may further include bimetallic or intermetallic metal nanoparticles including two or more metals selected from the group consisting of copper (Cu), zinc (Zn) and tin (Sn). Namely, the ink composition may include a mixture of metal chalcogenide nanoparticles including two or more phases and bimetallic or intermetallic metal nanoparticles.

The bimetallic or intermetallic metal nanoparticles may at least one selected from the group consisting of, for example, Cu—Sn bimetallic metal nanoparticles, Cu—Zn bimetallic metal nanoparticles, Sn—Zn bimetallic metal nanoparticles, and Cu—Sn—Zn intermetallic metal nanoparticles.

The inventors of the present invention confirmed that metal nanoparticles of the bimetallic or intermetallic are stable against oxidation, when compared to general metal nanoparticles, and may form a high-density film due to an increase in volume occurring by addition of a Group VI element, in a selenization process through heat treatment. Thus, by using an ink composition manufactured by mixing the bimetallic or intermetallic metal nanoparticles with the metal chalcogenide nanoparticles, film density is improved and the amount of a Group VI element in a final film is increased due to a Group VI element included in an ink composition, resulting in formation of an excellent quality CZTS/Se thin film.

A method of manufacturing the bimetallic or intermetallic metal nanoparticles, which is not limited specifically, may include a solution process using in particular, an organic reducing agent and/or inorganic reducing agent. The reducing agent may be one selected from the group consisting of, for example, LiBH₄, NaBH₄, KBH₄, Ca(BH₄)₂, Mg(BH₄)₂, LiB(Et)₃H, NaBH₃(CN), NaBH(OAc)₃, hydrazine, ascorbic acid and triethanolamine.

Here, the reducing agent may be 1 to 20 times, in a molar ratio, with respect to a total amount of the metal salts included in a solution process.

When the amount of the reducing agent in the metal salts is too small, reduction of the metal salts insufficiently occurs and thus an excessively small size or small amount of intermetallic or bimetallic metal nanoparticles may be obtained or it is difficult to obtain particles having a desired element ratio. In addition, when the amount of the reducing agent exceeds 20 times that of the metal salts, it is not easy to remove the reducing agent and by-products during the purifying process.

The size of the bimetallic or intermetallic metal nanoparticles manufactured according to the above process may be, in particular, approximately 1 to 500 nanometers.

In a specific embodiment, when the bimetallic or intermetallic metal nanoparticles and metal chalcogenide nanoparticles together are dispersed to manufacture an ink composition as described above, the metal nanoparticles and metal chalcogenide nanoparticles are mixed such that all of Cu, Zn, and Sn are included in the ink composition to adjust a composition ratio in a subsequent process. Here, the bimetallic or intermetallic metal nanoparticles and metal chalcogenide nanoparticles are not limited specifically so long as each of Cu, Zn and Sn is included in at least one particle of the metal nanoparticles and metal chalcogenide nanoparticles. In particular, the bimetallic or intermetallic metal nanoparticles may be Cu—Sn bimetallic metal nanoparticles and the metal chalcogenide nanoparticles may be the zinc (Zn)-containing chalcogenide-copper (Cu)-containing chalcogenide nanoparticles including the first phase and third phase. In addition, the bimetallic or intermetallic metal nanoparticles may be Cu—Zn bimetallic metal nanoparticles and the metal chalcogenide nanoparticles may be metal chalcogenide nanoparticles including two phases of the second phase and the third phase. In some cases, Cu—Zn—Sn intermetallic metal nanoparticles may be mixed with metal chalcogenide nanoparticles including the first phase, second phase and third phase.

Here, the Cu—Sn bimetallic nanoparticles may be more particularly CuSn or copper-enriched Cu—Sn particles such as Cu₃Sn, Cu₁₀Sn₃, Cu_{6.26}Sn₅, Cu₄₁Sn₁₁ Cu₆Sn₅ or the like, but the present invention is not limited thereto.

The Cu—Zn bimetallic nanoparticles may be, for example, Cu₅Zn₈, or CuZn.

Of course, when merely a composition ratio of a CZTS thin film is considered, merely the zinc (Zn)-containing chalcogenide nanoparticles or tin (Sn)-containing chalcogenide nanoparticles may be mixed with the metal nanoparticles, the zinc (Zn)-containing chalcogenide nanoparticles and copper (Cu)-containing chalcogenide nanoparticles each independently are synthesized and then mixed each other, or the tin (Sn)-containing chalcogenide nanoparticles and copper (Cu)-containing chalcogenide nanoparticles each independently are synthesized and then mixed each other. However, when sufficient mixing is not carried out during a thin film manufacture process, particles in some areas are respectively separated and thereby heterogeneity of a composition may occur. Such a problem may solved by using the metal chalcogenide nanoparticles according to the present invention including two elements in one particle such as, for example, Cu and Zn, Cu and Sn or the like.

In this case, the bimetallic or intermetallic metal nanoparticles may be mixed with the metal chalcogenide nanoparticles such that the composition of metal in an ink is 0.5≦Cu/(Zn+Sn)≦1.5 and 0.5≦Zn/Sn≦2, preferably 0.7≦Cu/(Zn+Sn)≦1.2 and 8≦Zn/Sn≦1.4 to provide a CZTS final thin film having maximum efficiency.

The present invention also provides a method of manufacturing thin film using the ink composition.

A method of manufacturing the thin film according to the present invention includes:

(i) preparing an ink (a) by dispersing at least one type of metal chalcogenide nanoparticles including two or more phases selected from the first phase including the zinc (Zn)-containing chalcogenide, the second phase including the tin (Sn)-containing chalcogenide and the third phase including the copper (Cu)-containing chalcogenide, in a solvent, or (b) by dispersing bimetallic or intermetallic metal nanoparticles, and metal chalcogenide nanoparticles including two or more phases selected from the first phase including zinc (Zn)-containing chalcogenide, the second phase including the tin (Sn)-containing chalcogenide and the third phase including the copper (Cu)-containing chalcogenide, in a solvent;

(ii) coating the ink on a base provided with an electrode; and

(iii) drying and then heat-treating the ink coated on the base provided with an electrode.

In the above, the phrase “including at least one type of metal chalcogenide nanoparticles” means including at least one selected from all types of metal chalcogenide nanoparticles, in particular, including all possible combinations selected from zinc (Zn)-containing chalcogenide-tin (Sn)-containing chalcogenide particles including the first phase and second phase, tin (Sn)-containing chalcogenide-copper (Cu)-containing chalcogenide particles including the second phase and the third phase, zinc (Zn)-containing chalcogenide-copper (Cu)-containing chalcogenide particles including the first phase and third phase, and zinc (Zn)-containing chalcogenide-tin (Sn)-containing chalcogenide-copper (Cu)-containing chalcogenide particles including the first phase, the second phase and the third phase.

In addition, embodiments and mix ratios of the bimetallic or intermetallic metal nanoparticles and the metal chalcogenide nanoparticles including two or more phases selected from the first phase including the zinc (Zn)-containing chalcogenide, the second phase including the tin (Sn)-containing chalcogenide and the third phase including the copper (Cu)-containing chalcogenide including are identical to those described above.

In a specific embodiment, the solvent of step (i) is not particularly limited so long as the solvent is a general organic solvent and may be one organic solvent selected from among alkanes, alkenes, alkynes, aromatics, ketones, nitriles, ethers, esters, organic halides, alcohols, amines, thiols, carboxylic acids, phosphines, phosphites, phosphates, sulfoxides, and amides or a mixture of at least one organic solvent selected therefrom.

In particular, the alcohols may be at least one mixed solvent selected from among ethanol, 1-propanol, 2-propanol, 1-pentanol, 2-pentanol, 1-hexanol, 2-hexanol, 3-hexanol, heptanol, octanol, ethylene glycol (EG), diethylene glycol monoethyl ether (DEGMEE), ethylene glycol monomethyl ether (EGMME), ethylene glycol monoethyl ether (EGMEE), ethylene glycol dimethyl ether (EGDME), ethylene glycol diethyl ether (EGDEE), ethylene glycol monopropyl ether (EGMPE), ethylene glycol monobutyl ether (EGMBE), 2-methyl-1-propanol, cyclopentanol, cyclohexanol, propylene glycol propyl ether (PGPE), diethylene glycol dimethyl ether (DEGDME), 1,2-propanediol (1,2-PD), 1,3-propanediol (1,3-PD), 1,4-butanediol (1,4-BD), 1,3-butanediol (1,3-BD), α-terpineol, diethylene glycol (DEG), glycerol, 2-(ethylamino)ethanol, 2-(methylamino)ethanol, and 2-amino-2-methyl-1-propanol.

The amines may be at least one mixed solvent selected from among triethyl amine, dibutyl amine, dipropyl amine, butylamine, ethanolamine, diethylenetriamine (DETA), triethylenetetramine (TETA), triethanolamine, 2-aminoethyl piperazine, 2-hydroxyethyl piperazine, dibutylamine, and tris(2-aminoethyl)amine.

The thiols may be at least one mixed solvent selected from among 1,2-ethanedithiol, pentanethiol, hexanethiol, and mercaptoethanol.

The alkanes may be at least one mixed solvent selected from among hexane, heptane, and octane.

The aromatics may be at least one mixed solvent selected from among toluene, xylene, nitrobenzene, and pyridine.

The organic halides may be at least one mixed solvent selected from among chloroform, methylene chloride, tetrachloromethane, dichloroethane, and chlorobenzene.

The nitriles may be acetonitrile.

The ketones may be at least one mixed solvent selected from among acetone, cyclohexanone, cyclopentanone, and acetyl acetone.

The ethers may be at least one mixed solvent selected from among ethyl ether, tetrahydrofuran, and 1,4-dioxane.

The sulfoxides may be at least one mixed solvent selected from among dimethyl sulfoxide (DMSO) and sulfolane.

The amides may be at least one mixed solvent selected from among dimethyl formamide (DMF) and n-methyl-2-pyrrolidone (NMP).

The esters may be at least one mixed solvent selected from among ethyl lactate, γ-butyrolactone, and ethyl acetoacetate.

The carboxylic acids may be at least one mixed solvent selected from among propionic acid, hexanoic acid, meso-2,3-dimercaptosuccinic acid, thiolactic acid, and thioglycolic acid.

However, the solvents are only given as an example, and embodiments of the present invention are not limited thereto.

In some cases, in preparing of the ink, the ink may be prepared by further adding an additive.

The additive may, for example, be at least one selected from the group consisting of a dispersant, a surfactant, a polymer, a binder, a crosslinking agent, an emulsifying agent, an anti-foaming agent, a drying agent, a filler, a bulking agent, a thickening agent, a film conditioning agent, an antioxidant, a fluidizer, a leveling agent, and a corrosion inhibitor. In particular, the additive may be at least one selected from the group consisting of polyvinylpyrrolidone (PVP), polyvinyl alcohol, Anti-terra 204, Anti-terra 205, ethyl cellulose, and DispersBYK110.

A method of forming a coating layer by coating the ink may, for example, be any one selected from the group consisting of wet coating, spray coating, spin-coating, doctor blade coating, contact printing, top feed reverse printing, bottom feed reverse printing, nozzle feed reverse printing, gravure printing, micro gravure printing, reverse micro gravure printing, roller coating, slot die coating, capillary coating, inkjet-printing, jet deposition, and spray deposition.

The heat treatment of step (iii) may be carried out at a temperature of 300 to 800° C.

Meanwhile, a selenization process may be included to prepare the thin film of a solar cell having much higher density. The selenization process may be carried out through a variety of methods.

As a first example, effects obtained from the selenization process may be achieved by manufacturing an ink by dispersing S and/or Se to particle types in a solvent with at least one type of metal chalcogenide nanoparticles or bimetallic or intermetallic metal nanoparticles and metal chalcogenide nanoparticles in step (i), and by combining the heat treatment of step (iii).

As a second example, effects obtained from the selenization process may be achieved through the heat treatment of step (iii) in the presence of S or Se

In particular, S or Se may be present by supplying H₂S or H₂Se in a gaseous state or supplying Se or S in a gaseous state through heating.

As a third example, after step (ii), S or Se may be stacked on the coated base, following by performing step (iii). In particular, the stacking process may be performed by a solution process or a deposition method.

The present invention also provides a thin film manufactured using the above-described method.

The thin film may have a thickness of 0.5 μm to 3.0 μm, more particularly 0.5 μm to 2.5 μm.

When the thickness of the thin film is less than 0.5 μm, the density and amount of the light absorption layer are insufficient and thus desired photoelectric efficiency may not be obtained. On the other hand, when the thickness of the thin film exceeds 3.0 μm, movement distances of carriers increase and, accordingly, there is an increased probability of recombination, which results in reduced efficiency.

The present invention also provides a thin film solar cell manufactured using the thin film.

A method of manufacturing a thin film solar cell is known in the art and thus a detailed description thereof will be omitted herein.

### BRIEF DESCRIPTION OF THE DRAWINGS

The above and other objects, features and other advantages of the present invention will be more clearly understood from the following detailed description taken in conjunction with the accompanying drawing, in which:

FIG. 1 is an image illustrating an EDS mapping result of ZnS—CuS nanoparticles showing uniform compositions of metals substituted with particles synthesized by reduction potential difference and metals substituting according to the present invention;

FIG. 2 is an image illustrating a line-scan result of ZnS—CuS nanoparticles showing uniform compositions of metals substituted with particles synthesized by reduction potential difference and metals substituting according to the present invention;

FIG. 3 is a scanning electron microscope (SEM) image of nanoparticles according to Example 1;

FIG. 4 is an X-ray diffraction (XRD) graph of nanoparticles according to Example 1;

FIG. 5 is an SEM image of nanoparticles according to Example 2;

FIG. 6 is an image illustrating EDX analysis of nanoparticles according to Example 2;

FIG. 7 is an XRD graph of nanoparticles according to Example 2;

FIG. 8 is an SEM image of nanoparticles according to Example 3;

FIG. 9 is an SEM image of nanoparticles according to Example 4;

FIG. 10 is an image illustrating an XRD result of nanoparticles according to Example 4;

FIG. 11 is an SEM image of nanoparticles according to Example 5;

FIG. 12 is an SEM image of nanoparticles according to Example 8;

FIG. 13 is an SEM image of nanoparticles according to Example 10;

FIG. 14 is an XRD graph of nanoparticles according to Example 10;

FIG. 15 is an SEM image of a section of a thin film according to Example 12;

FIG. 16 is an XRD graph of a section of a thin film according to Example 12;

FIG. 17 is an SEM image of a section of a thin film according to Example 13; and

FIG. 18 is an IV graph of a solar cell using a thin film of Example 12 according to Experimental Example 1.

### BEST MODE

Now, the present invention will be described in more detail with reference to the following examples. These examples are provided only for illustration of the present invention and should not be construed as limiting the scope and spirit of the present invention.

### EXAMPLE 1

### Synthesis of ZnS—CuS Particles

5 mmol of zinc chloride and 10 mmol of Na₂S were respectively dissolved in 50 ml of distilled water 50 ml. The dissolved solutions were mixed and then reacted for 2 hours at room temperature to manufacture ZnS nanoparticles.

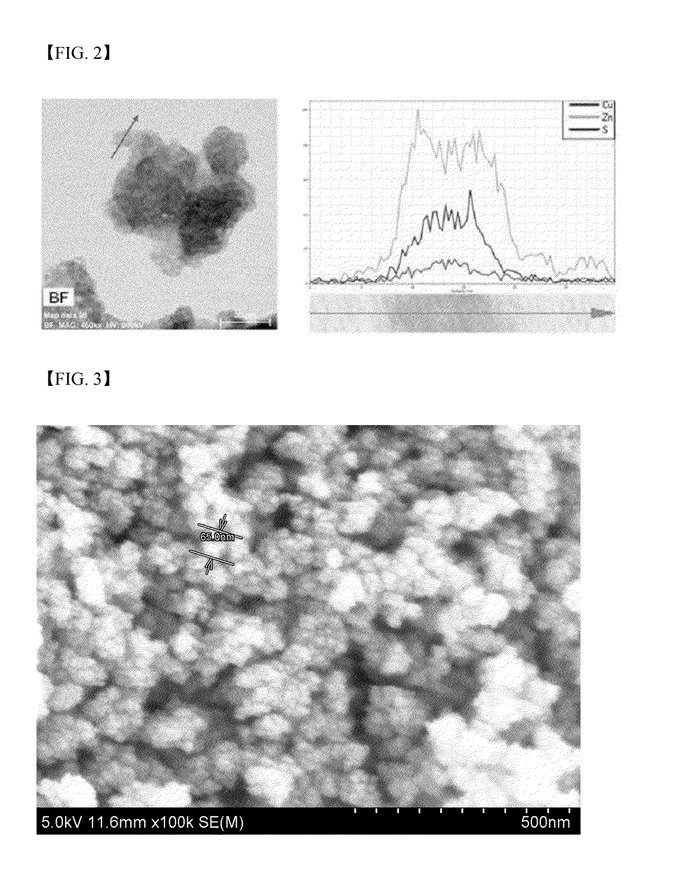

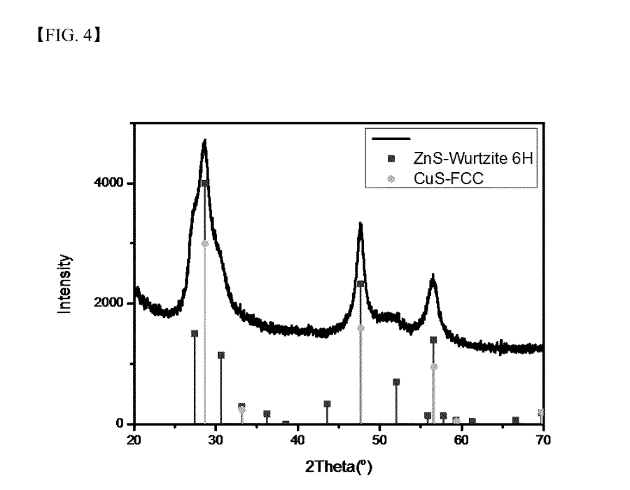

3 mmol of ZnS nanoparticles was dispersed in 30 ml of ethylene glycol (EG) 30 ml and then slowly added dropwise to a 0.6 mmol CuCl₂*2H₂O solution dissolved in 30 ml of EG while stirring. After stirring for 4 hours, ZnS—CuS particles in which Cu is substituted were obtained by purifying through centrifugation with ethanol. A scanning electron microscope (SEM) image and XRD graph of the formed particles are shown in FIGS. 3 and 4.

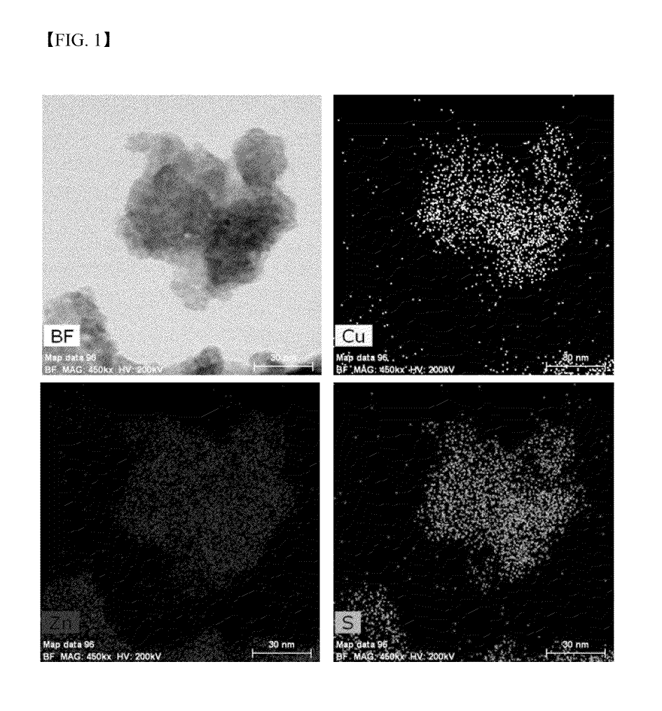

It was confirmed that the particles were chalcogenide particles having uniformly distributed Zn and Cu through EDS-mapping and line-scan, as shown in FIGS. 1 and 2.

### EXAMPLE 2

### Synthesis of ZnS—CuS Particles

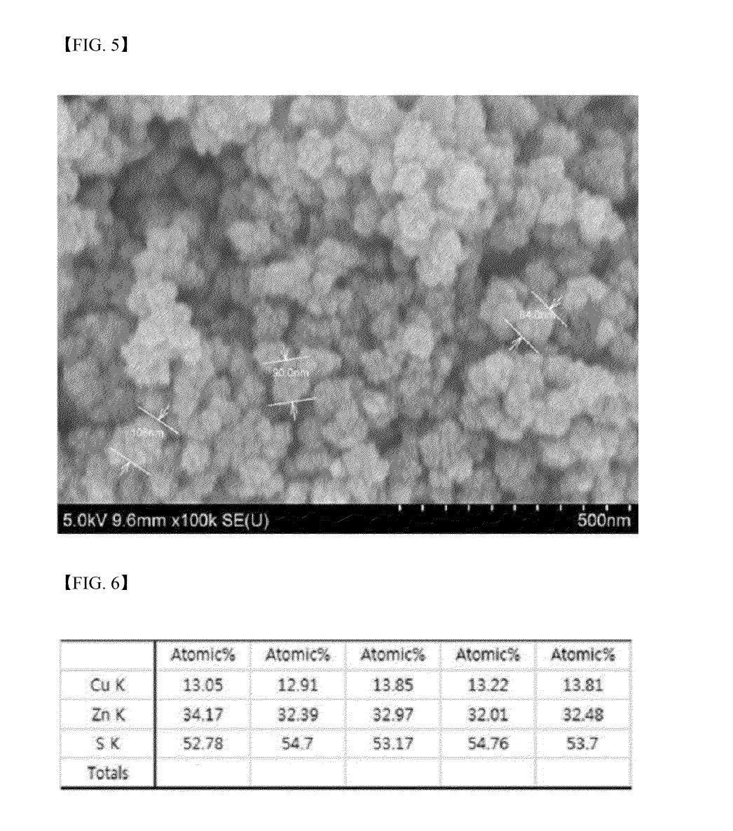

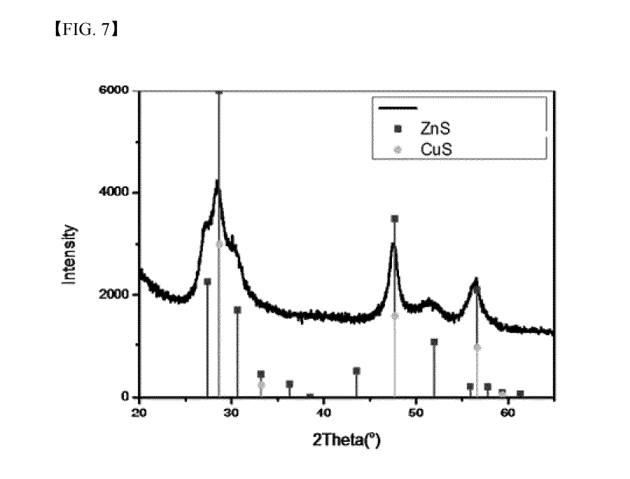

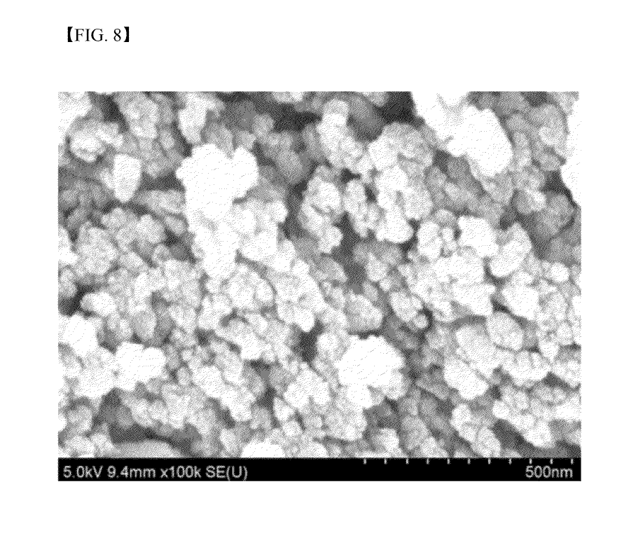

10 mmol of zinc chloride, 20 mmol of thioacetamide, 2 mmol of polyvinyl pyrrolidon were dissolved in 200 ml ethylene glycol and then reacted at 180° C. for 3 hours. Subsequently, the reacted product was purified through centrifugation, resulting in ZnS particles. The ZnS particles were vacuum-dried and then dispersed in 100 ml of ethylene glycol. Subsequently, 2.5 mmol of CuCl₂.2H₂O dissolved in 50 ml of ethylene glycol was added dropwise to the dispersed product. After reaction for 3 hours, the solution was purified through centrifugation, resulting in ZnS—CuS particles. An SEM image, EDX result, and XRD graph for the formed particles are shown in FIGS. 5 to 7.

### EXAMPLE 3

### Synthesis of ZnS—SnS particles

10 mmol of ZnS obtained in the same manner as in Example 2 was dispersed in 200 ml of ethanol and then 2.5 mmol SnCl₄ dissolved in 50 ml of ethanol was added dropwise thereto. The mix solution was stirred for 5 hours at 80° C. and then purified, resulting in ZnS—SnS particles. An SEM image of formed particles is shown in FIG. 8.

### EXAMPLE 4

### Synthsis of SnS—CuS Particles

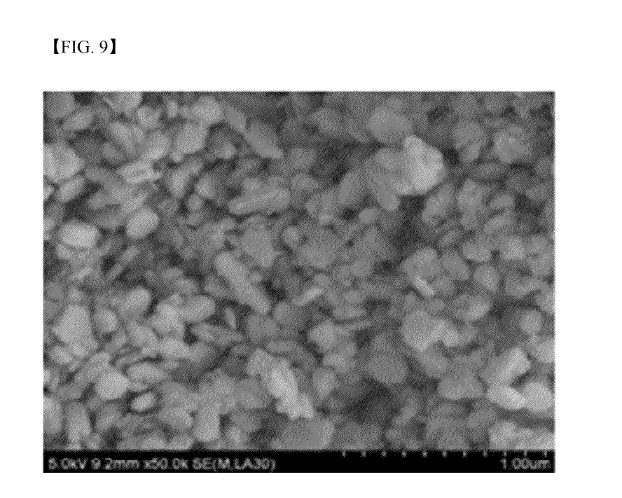

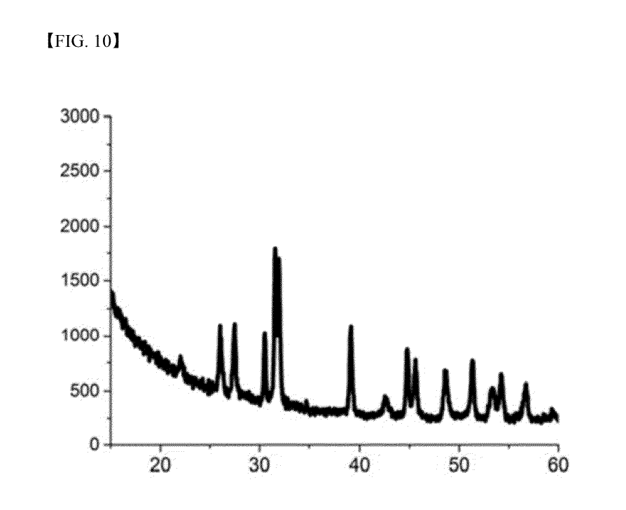

5 mmol of SnCl2, 5 mmol of thioacetamide and 1 mmol of polyvinyl pyrrolidon were dissolved in 100 ml of ethylene glycol and then reacted at 108□ for 3 hours. The reacted product was purified through centrifugation, resulting in SnS particles. The SnS particles were dispersed in 100 ml of ethylene glycol 100 ml and then 4 mmol of a CuCl2.2H2O solution was added dropwise thereto. Subsequently, the solution was stirred at 50° C. for 3 hours, resulting in SnS—CuS particles. An SEM image and XRD graph of the formed particles are shown in FIGS. 9 and 10.

### EXAMPLE 5

### Synthesis of ZnS—SnS—CuS Particles

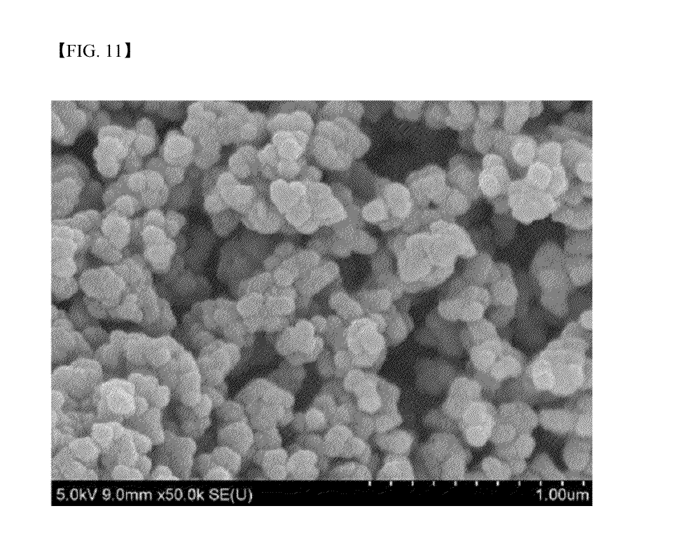

ZnS—SnS particles synthesized in the same manner as in Example 3 were dispersed in 100 ml of ethylene glycol 100 ml and then 4.5 mmol CuCl₂.2H₂O dissolved in ethylene glycol 50 ml was added dropwise thereto. Subsequently, the solution was stirred for 3 hours. As a result, ZnS—SnS—CuS nanoparticles having a ratio of Cu:Zn:Sn=4.5:3:2.5 were obtained. An SEM image for the formed particles is shown in FIG. 11.

### EXAMPLE 6

### Synthesis of ZnSe—CuSe Particles

20 mmol of NaBH₄ was dissolved in 50 ml of distilled water and then 10 mmol H₂SeO₃ dissolved in 50 ml of distilled water was added dropwise thereto. After stirring for 20 minutes, 10 mmol ZnCl₂ dissolved in 50 ml of distilled water was slowly added thereto. The resulting solution was stirred for 5 hours and then purified through centrifugation, resulting in ZnSe particles. The obtained particles were dispersed in 100 ml of ethanol and then 2.5 mmol copper acetate dissolved in 50 ml of ethanol was added dropwise thereto, resulting in ZnSe—CuSe particles. As determined by an inductively coupled plasma (ICP) analysis result of the formed particles, a ratio of Cu/Zn was 0.37.

### EXAMPLE 7

### Synthesis of ZnSe—SnSe Particles

ZnSe was synthesized in the same manner as in Example 6. Subsequently, obtained particles were dispersed in 100 ml of ethanol and then a 5 mmol tin chloride solution in dissolved 50 ml of ethanol was added dropwise thereto. Subsequently, the resulting solution was stirred at 50° C. for 3 hours and then purified through centrifugation, resulting in ZnSe—SnSe particles.

### EXAMPLE 8

### Synthesis of SnSe—CuSe Particles

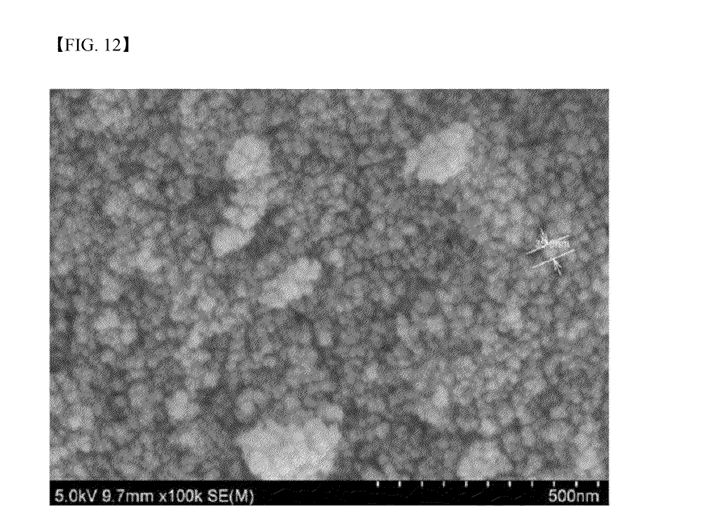

20 mmol of NaBH₄ was dissolved in 50 ml of distilled water and then 10 mmol H₂SeO₃ dissolved in 25 ml of distilled water was added dropwise thereto. After stirring for 20 minutes, 10 mmol ZnCl₂ dissolved in 25 ml of distilled water was added thereto. The resulting solution was reacted for 3 hours and then purified, resulting in SnSe particles. The obtained particles were dispersed in 100 ml of ethanol and then 2.5 mmol CuCl₂.2H₂O dissolved in 50 ml of ethanol was added dropwise thereto. This solution was stirred at 50° C. for 3 hours and then purified, resulting in SnSe—CuSe particles. An SEM image of the formed particles is shown in FIG. 12.

### EXAMPLE 9

### Synthesis of ZnSe—SnSe—CuSe Particles

ZnSe—SnSe particles synthesized in the same manner as in Example 7 were dispersed in 100 ml of ethylene glycol 100 ml and then 3 mmol CuCl₂.2H₂O dissolved in 50 ml of ethylene glycol was added dropwise thereto. Subsequently, the solution was stirred for 3.5 hours and then purified through centrifugation. As a result, ZnSe—SnSe—CuSe particles having a ratio of Cu:Zn:Sn=4.5:3:2.4 were obtained.

### EXAMPLE 10

### Synthesis of Cu—Sn Particles

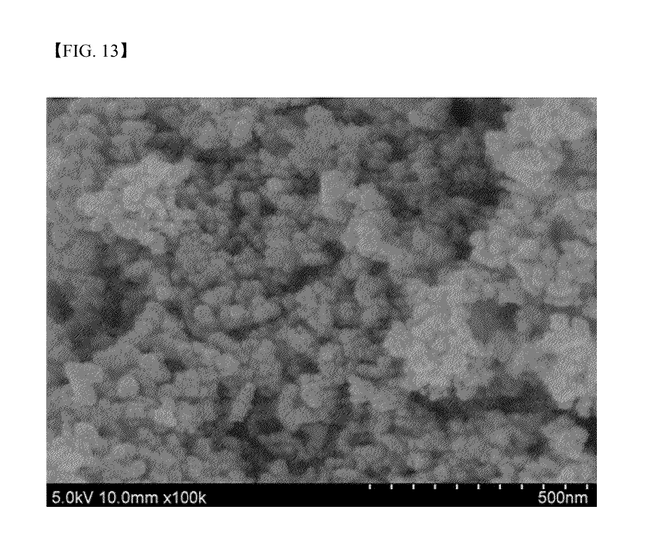

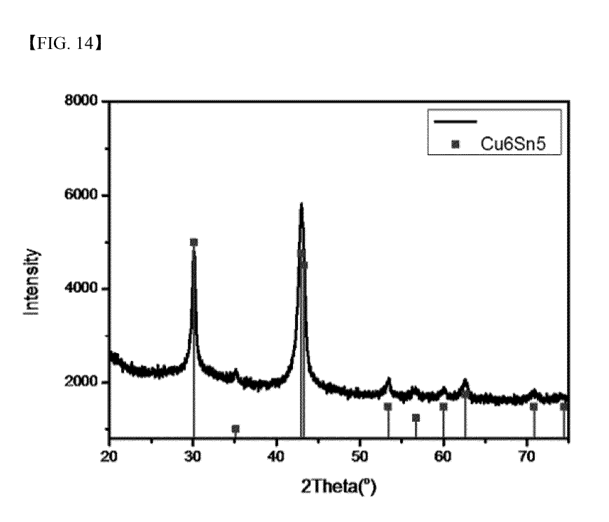

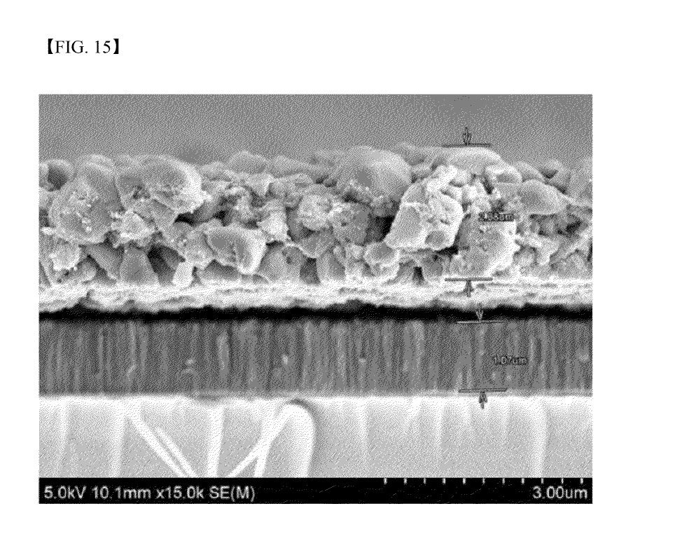

A mixed aqueous solution including 12 mmol CuCl₂, 10 mmol SnCl₂ and 50 mmol trisodium citrate was added over the course of 1 hour to an aqueous solution including 60 mmol NaBH₄ and then reacted while stirring for 24 hours. The formed particles were purified through centrifugation, resulting in Cu₆Sn₅ bimetallic nano particles. An SEM image and XRD graph of the formed particles are shown in FIGS. 13 and 14.

### Comparative Example 1

### Synthesis of CuS, ZnS, SnS Particles

Each of ZnS and SnS was synthesized in the same manner as in Examples 2 and 4. To manufacture CuS, 10 mmol of Cu(NO₃)₂ and 10 mmol of thioacetamide was respectively dissolved and mixed in two separate ethylene glycol solutions of 50 ml. The resulting two mixture were respectively reacted at 150° C. for 3 hours, resulting in CuS particles.

### EXAMPLE 11

### Manufacture of Thin Film

The ZnS—CuS particles according to Example 1 and the Cu—Sn bimetallic metal particles according to Example 10 were mixed satisfying the following conditions: Cu/(Zn+Sn)=0.9, Zn/Sn=1.24. Subsequently, this mixture was added to a mixed solvent including ethanol, ethylene glycol monomethyl ether, acetylacetone, propylene glycol propyl ether, cyclohexanone and propanol, and then dispersed at a concentration of 18%, so as to manufacture an ink. The obtained ink was coated on a Mo thin film coated on a glass and then dried up to 200° C. The coated thin film was heat-treated at 550° C. in the presence of Se, resulting in a CZTS thin film.

### EXAMPLE 12

### Manufacture of Thin Film

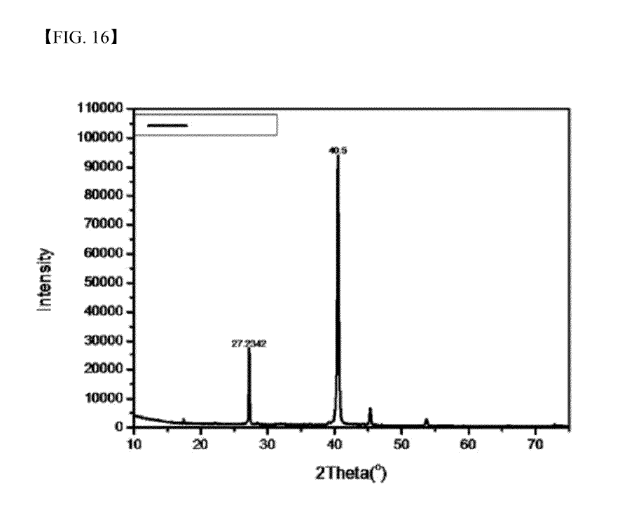

The ZnS—CuS particles according to Example 2 and the Cu—Sn bimetallic metal particles according to Example 10 were mixed satisfying the following conditions: Cu/(Zn+Sn)=0.85, Zn/Sn=1.26. Subsequently, this mixture was added to a mixed solvent including ethanol, ethylene glycol monomethyl ether, acetylacetone, propylene glycol propyl ether, cyclohexanone and propanol, and then dispersed at a concentration of 18%, so as to manufacture an ink. The obtained ink was coated on a Mo thin film coated on glass and then dried up to 200° C. The coated thin film was heat-treated at 575° C. in the presence of Se, resulting in a CZTS thin film. A section and XRD phase of the obtained thin film are shown in FIGS. 15 and 16.

### EXAMPLE 13

### Manufacture of Thin Film

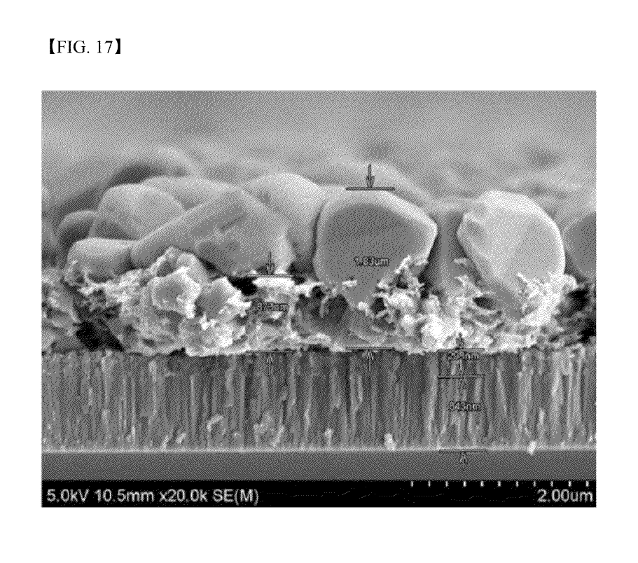

The ZnS—CuS particles according to Example 2 and the SnS—CuS particles according to Example 4 were mixed satisfying the following conditions: Cu/(Zn+Sn)=0.92, Zn/Sn=1.15. Subsequently, this mixture was added to a mixed solvent including ethanol, ethylene glycol monomethyl ether, acetylacetone, propylene glycol propyl ether, cyclohexanone and propanol, and then dispersed at a concentration of 16%, so as to manufacture an ink. The obtained ink was coated on a Mo thin film coated on glass and then dried up to 200° C. The coated thin film was heat-treated at 575° C. in the presence of Se, resulting in a CZTS thin film. A section of the obtained thin film is shown in FIG. 17.

### EXAMPLE 14

### Manufacture of Thin Film

The ZnS—SnS—CuS particles according to Example 5 was added to a mixed solvent including ethanol, ethylene glycol monomethyl ether, acetylacetone, propylene glycol propyl ether, cyclohexanone and propanol, and then dispersed at a concentration of 16%, so as to manufacture an ink. The obtained ink was coated on a Mo thin film coated on glass and then dried up to 200° C. The coated thin film was heat-treated at 575° C. in the presence of Se, resulting in a CZTS thin film.

### EXAMPLE 15

### Manufacture of Thin Film

A CZTS thin film was manufactured in the same manner as in Example 12 except that the ZnSe—CuSe particles manufactured according to Example 6 were mixed with the Cu—Sn bimetallic metal particles manufactured according to Example 10 so as to manufacture an ink.

### EXAMPLE 16

### Manufacture of Thin Film

A CZTS thin film was manufactured in the same manner as in Example 14 except that the ZnSe—SnSe—CuSe particles manufactured according to Example 9 were used to manufacture an ink.

### EXAMPLE 17

### Manufacture of Thin Film

A CZTS thin film was manufactured in the same manner as in Example 13 except that the ZnSe—CuSe particles manufactured according to Example 6 were mixed with the SnSe—CuSe particles particles manufactured according to Example 8 so as to manufacture an ink.

### EXAMPLE 18

### Manufacture of Thin Film

A CZTS thin film was manufactured in the same manner as in Example 13 except that the ZnS—CuS particles manufactured according to Example 2 were mixed with the SnSe—CuSe particles manufactured according to Example 8 so as to manufacture an ink.

### Comparative Example 2

### Manufacture of Thin Film

A CZTS thin film was manufactured in the same manner as in Example 13 except that the CuS particles, ZnS particles, SnS particles manufactured according to Comparative Example 1 were mixed so as to manufacture an ink.

### Experimental Example 1

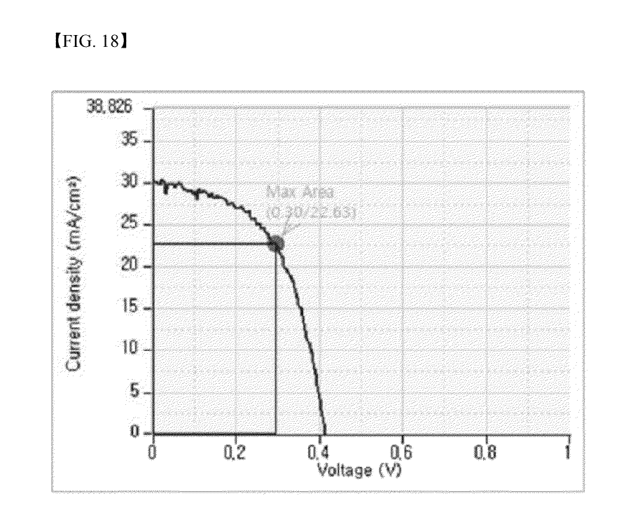

CdS buffer layers were formed by CBD and then ZnO and Al:ZnO were sequentially stacked by sputtering on the CZTS thin films manufactured according to Examples 11 to 18 and Comparative Example 2. Subsequently, Al electrodes were disposed on the thin films by e-beam, completing fabrication of cells. Characteristics of the cells are summarized in Table 1 below and FIG. 18.

TABLE 1

| | | | | Photoelectric |
|---|---|---|---|---|
| | J_{sc} (mA/cm²) | V_{oc} (V) | FF (%) | efficiency (%) |
| Example 11 | 34.0 | 0.40 | 44.5 | 6.04 |
| Example 12 | 30.24 | 0.41 | 54.7 | 6.8 |
| Example 13 | 33.9 | 0.36 | 40.4 | 4.93 |
| Example 14 | 32.2 | 0.37 | 38.5 | 4.57 |
| Example 15 | 29.34 | 0.38 | 50.5 | 5.63 |
| Example 16 | 29.34 | 0.37 | 38.47 | 4.57 |
| Example 17 | 25.14 | 0.38 | 25.72 | 2.45 |
| Example 18 | 24.2 | 0.37 | 25.7 | 2.30 |
| Comparative | 10.0 | 0.32 | 23.8 | 0.75 |
| Example 2 | | | | |

In Table 1, J_{sc}, which is a variable determining the efficiency of each solar cell, represents current density, V_{oc} denotes an open circuit voltage measured at zero output current, the photoelectric efficiency means a rate of cell output according to irradiance of light incident upon a solar cell plate, and fill factor (FF) represents a value obtained by dividing a value obtained by multiplication of current density and voltage values at a maximum power point by a value obtained by multiplication of Voc by J_{sc}.

Referring to Table 1 and FIG. 18, the CZTS thin films manufactured using the metal chalcogenide nanoparticles according to the present invention showed improvement in the current intensity, open circuit voltage, open circuit voltage, and photoelectric efficiency, when compared to nanoparticles manufactured by mixing nanoparticles including the prior only one metal element. Especially, the current intensity and open circuit voltage of the CZTS thin films manufactured using the metal chalcogenide nanoparticles according to the present invention were extremely superior.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

### INDUSTRIAL APPLICABILITY

As described above, metal chalcogenide nanoparticles according to the present invention include two or more phases selected from a first phase including a zinc (Zn)-containing chalcogenide, a second phase including a tin (Sn)-containing chalcogenide, and a third phase including a copper (Cu)-containing chalcogenide in one particle. When a thin film is manufactured using the metal chalcogenide nanoparticles, one particle includes two or more metals and, as such, the composition of the thin film is entirely uniform. In addition, since nanoparticles include S or Se, the nanoparticles are stable against oxidation. Furthermore, when a thin film is manufactured further including metal nanoparticles, the volumes of particles are extended in a selenization process due to addition of a Group VI element and thereby light absorption layers having high density may grow, and accordingly, the amount of the Group VI element in a final thin film is increased, resulting in a superior quality thin film.

1. Metal chalcogenide nanoparticles forming light absorption layers of solar cells comprising two or more phases selected from a first phase comprising a zinc (Zn)-containing chalcogenide, a second phase comprising a tin (Sn)-containing chalcogenide and a third phase comprising the copper (Cu)-containing chalcogenide.

2. The metal chalcogenide nanoparticles according to claim 1, wherein the copper (Cu)-containing chalcogenide is CuₓS wherein 0.5≦x≦2.0, and/or Cu_{y}Se wherein 0.5≦y≦2.0,
wherein the zinc (Zn)-containing chalcogenide is ZnS, and/or ZnSe, and wherein the tin (Sn)-containing chalcogenide is Sn_{z}S wherein 0.5≦z≦2.0 and/or Sn_{w}Se wherein 0.5≦w≦2.0.

3.-5. (canceled)

6. The metal chalcogenide nanoparticles according to claim 1, wherein the metal chalcogenide nanoparticles comprise two phases, and the two phases are the first phase and the second phase, or the second phase and the third phase, or the first phase and the third phase.

7. The metal chalcogenide nanoparticles according to claim 6, wherein the two phases comprise the first phase and the second phase, and a ratio of to the tin to the zinc satisfies 0<Sn/Zn.

8. The metal chalcogenide nanoparticles according to claim 6, wherein the two phases comprise the second phase and the third phase, and a ratio of the copper to the tin is 0<Cu/Sn.

9. The metal chalcogenide nanoparticles according to claim 6, wherein the two phases comprise the first phase and the third phase, and a ratio of the copper to zinc satisfies 0<Cu/Zn.

10. The metal chalcogenide nanoparticles according to claim 6, wherein one phase of the two phases forms a core, and the other one phase forms a shell.

11. (canceled)

12. The metal chalcogenide nanoparticles according to claim 1, comprising three phases comprising the first phase, the second phase and the third phase.

13. The metal chalcogenide nanoparticles according to claim 12, wherein a composition ratio of zinc, tin, and copper comprised in the three phases satisfies the following conditions: 0.5≦Cu/(Zn+Sn)≦1.5 and 0.5≦Zn/Sn≦2.

14. The metal chalcogenide nanoparticles according to claim 12, wherein one phase of the three phases forms a core, and the other two phases form a shell as a complex form.

15. The metal chalcogenide nanoparticles according to claim 12, wherein two phases of the three phases form a core as a complex form, and the other one phase forms a shell.

16. (canceled)

17. The metal chalcogenide nanoparticles according to claim 1, wherein the metal chalcogenide nanoparticles are manufactured by substitution reaction using reduction potential differences of the zinc (Zn), the tin (Sn) and the copper (Cu).

18. A method of synthesizing metal chalcogenide nanoparticles, the method comprising:
manufacturing a first precursor comprising zinc (Zn) or tin (Sn), and sulfur (S) or selenium (Se), and then
some of the zinc (Zn) of the first precursor is substituted with the tin (Sn) and/or the copper (Cu) by reduction potential differences of metals, or some of the tin (Sn) of the first precursor is substituted with copper (Cu) by a reduction potential difference of metals.

19. The method according to claim 18, wherein the first precursor comprises:
preparing a first solution comprising at least one Group VI source selected from the group consisting of compounds comprising sulfur (S), or selenium (Se), or sulfur (S) and selenium (Se);
(ii) preparing a second solution comprising the zinc (Zn) salt or the tin (Sn) salt; and
(iii) mixing and reacting the first solution and the second solution.

20. The method according to claim 18, wherein, to substitute using reduction potential differences of the metals, a product comprising the first precursor is mixed and reacted with a third solution comprising the tin (Sn) salt and/or the copper (Cu) salt.

21. The method according to claim 18, wherein, to substitute some of the zinc (Zn) of the first precursor with the tin (Sn) and the copper (Cu) using reduction potential differences of metals, a product comprising the first precursor is sequentially mixed and reacted with a third solution comprising the tin (Sn) salt and a fourth solution comprising the copper (Cu) salt.

22.-24. (canceled)

25. An ink composition for manufacturing light absorption layers comprising at least one type of the metal chalcogenide nanoparticles according to claim 1.

26. The ink composition according to claim 25, further comprising bimetallic or intermetallic metal nanoparticles comprising two or more metals selected from the group consisting of copper (Cu), zinc (Zn) and tin (Sn).

27. The ink composition according to claim 26, wherein the bimetallic or intermetallic metal nanoparticles are at least one selected from the group consisting of Cu—Sn bimetallic metal nanoparticles, Cu—Zn bimetallic metal nanoparticles, Sn—Zn bimetallic metal nanoparticles and Cu—Sn—Zn intermetallic metal nanoparticles.

28. The ink composition according to claim 26, wherein the bimetallic or intermetallic metal nanoparticles are mixed with the metal chalcogenide nanoparticles such that a metal composition in the ink composition is in a range of 0.5≦Cu/(Zn+Sn)≦1.5 and 0.5≦Zn/Sn≦2.

29.-36. (canceled)
